(19) United States
(12) Patent Application Publication
(10) Pub. No.: US 2014/0151721 A1
(43) Pub. Date: Jun. 5, 2014

(54) PHASE TRANSITION COOLING IN LED LIGHTING DEVICES

(71) Applicant: CORNING INCORPORATED, Corning, NY (US)

(72) Inventors: Timothy James Orsley, San Jose, CA (US); William Richard Trutna, Atherton, CA (US)

(73) Assignee: CORNING INCORPORATED, Corning, NY (US)

(21) Appl. No.: 13/828,190

(22) Filed: Mar. 14, 2013

Related U.S. Application Data
(60) Provisional application No. 61/731,584, filed on Nov. 30, 2012.

(51) Int. Cl. H01L 33/64

(52) U.S. Cl. CPC H01L 33/648
USPC 257/88

(57) ABSTRACT

A lighting device is provided comprising a chip-on-board (COB) light emitting diode (LED) light source, a phase transfer fluid disposed in a hermetically sealed phase transfer fluid chamber, a phase transfer fluid wicking structure, a distributed color conversion medium, and a glass containment plate. The color conversion medium is distributed in two dimensions over an emission field of the lighting device within the glass containment plate. The COB LED light source comprises a thermal heat sink framework and at least one LED and defines the hermetically sealed phase transfer fluid chamber in which the phase transfer fluid is disposed. The glass containment plate is positioned over the hermetically sealed phase transfer fluid chamber and contains the distributed color conversion medium. The phase transfer fluid wicking structure is transparent to at least a portion of the operating wavelength bandwidth of the LED and is configured within the hermetically sealed phase transfer fluid chamber to encourage transport of phase transfer fluid, permit vaporization of transported phase transfer fluid, and receive condensed phase transfer fluid vapor.

### CROSS REFERENCE TO RELATED APPLICATION

The present application claims priority to U.S. Provisional Application Ser. No. 61/731,584, filed Nov. 30, 2012 (SP12-371P).

### BACKGROUND

1. Field

The present disclosure relates to light emitting diode (LED) lighting devices and, more particularly, packaged chip-on-board (COB) LED arrays.

2. Technical Background

Referring initially to FIG. 1, high brightness LED lighting devices, i.e., light sources approaching or exceeding 1000 lumens, typically require a significant number of blue LEDs 10 configured in a two-dimensional array that is secured, for example, to a metal clad PC board 20. In many cases, the diode array is covered by a color conversion phosphor dispersed in a silicone encapsulant 30. These and other types of COB LED arrays are becoming standardized in shape, light output, and electrical drive requirements and could conceivably become the new lighting standard.

### BRIEF SUMMARY

The present inventors have recognized that a significant metric for packaged chip-on-board (COB) LED arrays is light output, measured in lumens per LED, with the understood objective of maximizing light output per LED while minimizing cost per LED. Light output per LED is, however, limited by the temperature rise of the phosphor and the impact of that rise on the surrounding silicone. Due to the inherent conversion inefficiency of the phosphor as well as Stokes shift during color conversion, some of the blue light is converted into heat, which can be removed by thermal conduction through the LED to an underlying heat sink. Unfortunately, the silicone potting compound in which the phosphor is mixed has a relatively low thermal conductivity—a condition that can cause a significant temperature rise in the phosphor-in-silicone film. For example, given a heat sink temperature of 85° C. @ 1000 lumens, the temperature of the phosphor-in-silicone film can reach 160 degrees, which is the maximum operating temperature of the silicone but typically does not correspond to the maximum light output or temperature of the LED. Accordingly, the present disclosure introduces means by which heat can be more efficiently removed from the color converting layer of an LED lighting device to allow the LED(s) of the device to be driven harder, increasing total light output.

For example, in chip-on-board (COB) LED arrays, blue LEDs are often encapsulated in what starts out as a slurry of phosphor and silicone. The thickness of the phosphor-in-silicone (PiS) above the LEDs has been measured at 750 μm. This is sufficient to convert a portion of the blue light to longer wavelengths while allowing some of the blue light to pass through unconverted. As the blue light is converted by the phosphor, some heating occurs due to quantum efficiency being less than perfect, e.g., about 95%. Additional heating occurs due to Stokes shift as a higher energy blue photon is traded for a lower energy photon of longer wavelength. Since silicone is a relatively poor thermal conductor, this heat turns out to limit the output of the blue LEDs. That is, if the blue LEDs were driven harder, then the PiS would heat to the point that the silicone would become damaged.

According to the subject matter of the present disclosure, packaged chip-on-board (COB) LED arrays are provided where a color conversion medium is distributed within a glass containment plate, rather than silicone, to reduce the operating temperature of the color conversion medium and avoid damage while increasing light output. The glass containment plate may be provided as a glass containment frame comprising an interior volume for containing a color conversion medium, a glass containment matrix in which the color conversion is distributed, or any other substantially planar structural glass member, vessel, or assembly suitable for containing the color conversion medium.

This structure is beneficial in a number of ways. First the color conversion medium can itself withstand higher temperature than cases where the medium is dispersed in silicon because the glass containment plate has no organic component. The glass containment plate of the present disclosure is also beneficial because it provides for additional manufacturing process control. Specifically, the plate can be tested separately from the corresponding LED array and an appropriate plate-to-array pairing can be made to achieve the desired color output. This is not the case when a conversion medium is provided as a slurry in the silicone used to encapsulate the LED array. Finally, the glass containment plate of the present disclosure is beneficial because it helps to define a hermetically sealed phase transfer fluid chamber that can be used to help remove heat from the LED array.

In accordance with one embodiment of the present disclosure, a lighting device is provided comprising a chip-on-board (COB) light emitting diode (LED) light source, a phase transfer fluid disposed in a hermetically sealed phase transfer fluid chamber, a phase transfer fluid wicking structure, a distributed color conversion medium, and a glass containment plate. The color conversion medium is distributed in two dimensions over an emission field of the lighting device within the glass containment plate. The COB LED light source comprises a thermal heat sink framework and at least one LED and defines the hermetically sealed phase transfer fluid chamber in which the phase transfer fluid is disposed. The glass containment plate is positioned over the hermetically sealed phase transfer fluid chamber and contains the distributed color conversion medium. The phase transfer fluid wicking structure is transparent to at least a portion of the operating wavelength bandwidth of the LED and is configured within the hermetically sealed phase transfer fluid chamber to encourage transport of phase transfer fluid, permit vaporization of transported phase transfer fluid, and receive condensed phase transfer fluid vapor.

In accordance with another embodiment of the present disclosure, the distributed color conversion medium comprises a phosphor distributed in a glass matrix and the lighting device further comprises a quantum dot plate disposed over the glass containment plate to define a supplemental emission field of the lighting device.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 illustrates an LED lighting device employing a phosphor-in-silicone color conversion medium;

FIGS. 2-4 are schematic illustrations of LED lighting devices according to some embodiments of the present disclosure.

### DETAILED DESCRIPTION

FIGS. 2-4 illustrate COB LED lighting devices 100, 100′, 100″ that comprise an array of LEDs 110, a phase transfer fluid disposed in a hermetically sealed phase transfer fluid chamber 115, a phase transfer fluid wicking structure 120, a distributed color conversion medium 130, 130′, a glass containment plate 140, 140′, a glass cover plate 145, and a thermal heat sink framework 150 in the form of, for example, a metal clad printed circuit board. The phase transfer fluid is not illustrated in FIGS. 2-4 because it typically occupies a small fraction of the total chamber volume and, as will be described in further detail below, principally moves through the wicking structure 120 along fluid transport paths 125 or is transported as vapor along vapor transport paths 135.

The color conversion medium 130, 130′ is distributed in two dimensions over an emission field of the LED lighting device within the glass containment plate 140, 140′ and may comprise, for example, a color converting phosphor or a quantum dot structure. Notably, the lighting devices 100, 100′, 100″ do not encapsulate the LED 110 in silicone or any other light source encapsulant. Beyond that which is disclosed herein, the specific materials selected for the color conversion medium 130, 130′, glass containment plate 140, 140′, cover plate 145, and the thermal heat sink framework 150 can be gleaned from references like US PG Pub. No. 2012/0107622, which relates primarily to the use of color converting phosphors in LED lighting devices, US 2012/0175588, which relates to the use of light-converting, colloidal, doped semiconductor nanocrystals to provide monochromatic and white light sources based on LEDs, and U.S. Pat. No. 7,723,744, which relates to light-emitting devices that incorporate one or more underlying LED chips or other light sources and a layer having one or more populations of nanoparticles disposed over the light source. The nanoparticles absorb some light emitted by the underlying source, and re-emit light at a different level. By varying the type and relative concentration of nanoparticles, different emission spectra may be achieved.

As is noted above, the present disclosure introduces means by which heat can be more efficiently removed from the color converting layer of an LED lighting device and means that allow for a greater absolute temperature rise in the color converting layer. Both of these factors allow the LED(s) of the device to be driven harder, increasing total light output. To this end, the glass containment plate 140, 140′, which contains the distributed color conversion medium 130 and defines high operating temperature regions T_{H} of the lighting device, is positioned over the hermetically sealed phase transfer fluid chamber 115. For the purposes of the present disclosure, it should be understood that hermetic seals are substantially airtight seals that prevent significant ingress of oxygen, moisture, humidity, and any outside contaminant.

In contrast, the thermal heat sink framework 150 of the light source 100, 100′, 100″ defines low operating temperature regions T_{C}. Taking advantage of this operating temperature contrast, the phase transfer fluid wicking structure 120 is configured within the hermetically sealed phase transfer fluid chamber 115 to function like a “heat pipe” by enabling phase transfer fluid vaporization at the relatively hot regions adjacent to the glass containment plate 140, 140′. This vaporization removes heat from the glass containment plate 140, 140′ and the contained color conversion medium 130, 130′. The heat-loaded vapor is subsequently transported along vapor transport paths 135 to the relatively cold heat sink 150 where it condenses, giving up heat. To complete the cycle, the phase transfer fluid returns to the aforementioned hot spots along fluid transport paths 125 in the wicking structure 120. Notably, heat flow is through vapor transport rather than thermal conduction.

More specifically, the phase transfer fluid wicking structure 120 is transparent to at least a portion of the operating wavelength bandwidth of the LEDs 110 and is configured within the hermetically sealed phase transfer fluid chamber 115 to
(i) encourage the transport of phase transfer fluid along a fluid transport path extending from low operating temperature regions T_{C} of the lighting device to high operating temperature regions T_{H} of the lighting device within the fluid chamber,
(ii) permit vaporization of the transported phase transfer fluid in the high operating temperature regions T_{H} of the lighting device, and
(iii) receive condensed phase transfer fluid vapor in the low operating temperature regions T_{C} of the lighting device for return transport to the high operating temperature regions T_{H} of the lighting device via the phase transfer fluid wicking structure.

Typically, the phase transfer fluid wicking structure 120 encourages the transport of phase transfer fluid through capillary action but the concepts of the present disclosure are by no means limited to wicking structures that operate through capillary action. For example, and not by way of limitation, the phase transfer fluid wicking structure 120 may comprise a wicking media, such as a sintered glass frit, disposed on an interior surface of the hermetically sealed phase transfer fluid chamber 115. Alternatively, the phase transfer fluid wicking structure 120 may comprise fluid transfer grooves, a glass mesh, glass fiber network, or other topographical formations designed to overcome surface tension and encourage fluid transport along an interior surface of the hermetically sealed phase transfer fluid chamber 115.

In the illustrated embodiments, the fluid wicking structure 120 extends from a chip-on-board portion of the thermal heat sink framework 150 to those portions of the hermetically sealed phase transfer fluid chamber 115 that are in closest thermal communication with the distributed color conversion medium 130, 130′. The fluid wicking structure 120 extends from the low operating temperature regions T_{C} of the lighting device to the high operating temperature regions T_{H} of the lighting device. In many cases it will be preferable to ensure that the fluid transport paths 125 of the wicking structure 120 extends along an indirect route from the low operating temperature regions T_{C} of the lighting device to the high operating temperature regions T_{H} of the lighting device. Further, it will often be advantageous to ensure that this indirect route is configured such that a significant portion of the fluid transport paths 125 lie outside of the vapor transport paths 135 defined between the high operating temperature regions T_{H} of the lighting device and the low operating temperature regions T_{C} of the lighting device.

Referring specifically to the configurations of FIGS. 2 and 3, it is noted that the glass cover plate 145 is disposed over the glass containment plate 140, with ion exchanged glass being a suitable contemplated glass composition choice for the glass cover plate 145. The glass containment plate 140 can be permanently bonded to the glass cover plate 145 during firing of the two, to consolidate the frit of the glass containment plate 140. In many embodiments, particularly where the glass containment plate 140 is provided as a glass containment matrix in which the color conversion medium 130 is distributed, it will be advantageous to provide the glass containment plate by tape casting the material of the glass containment plate to a glass substrate and then bonding that substrate to the cover glass plate 145, which occurs during consolidation of the frit. However, it is contemplated that the material of the glass containment plate 140 may be tape cast directly onto the cover glass plate 145, thus avoiding the need to bond the glass containment plate 140 to the cover glass plate 145. It is also noted that while the glass containment plate 140 is capable of transporting heat, this thermal conduction mechanism is insignificant compared to the thermal transport provided by the thermal transfer fluid and the fluid wicking structure 120.

In the embodiment of FIG. 3, the LED lighting device 100′ further comprises a quantum dot plate 160 disposed over the glass cover plate 145 to define a supplemental emission field of the LED lighting device 100′. The quantum dot plate 160 comprises a quantum dot structure 170 that is contained within an interior volume defined between opposing, sealed glass panels 160a, 160b of the quantum dot plate 160. The primary emission field that is defined by the distributed phosphor color conversion medium 130 is spatially congruent with, but spectrally distinct from, the supplemental emission field defined by the quantum dot plate 160. In this manner, the emission spectrum of the emission field defined by the quantum dot plate 160 can be tailored to add optical warmth, a reduction in color temperature, to the emission spectrum of the emission field defined by the distributed phosphor color conversion medium 130. For example, where the distributed phosphor color conversion medium 130 converts blue light from the LEDs 110 to yellow, the quantum dots of the quantum dot plate can be tailored to add warmth by converting some of the yellow light, as well as leaking blue light, to red—one advantage being that red quantum dots have a relatively narrow emission band, unlike red phosphors which waste light by tailing into the IR. In the case of red quantum dots, since quantum dots have a relatively narrow emission band, the issue of tailing into the IR can be avoided thus preserving good power efficiency. As an alternative to selecting a quantum dot plate of a particular color, it is contemplated that the sizes of the quantum dots contained can be adjusted to obtain the desired color. It is also contemplated that a variety of quantum dot sizes can also be blended to obtain a particular color, e.g., white.

Referring specifically to the configuration of FIG. 4, it is noted that the glass containment plate 140′ is presented in the form of a glass containment frame comprising an interior volume defined between opposing, sealed glass panels 140a, 140b for containing the distributed color conversion medium 130′. The distributed color conversion medium 130′ may be provided in the form of the quantum dot structure described above with reference to FIG. 3. More specifically, it is contemplated that the distributed color conversion medium 130′ may comprise a quantum dot structure contained within the interior volume defined by the opposing glass panels 140a, 140b, with flexible fusion glass being a suitable contemplated glass composition choice. In FIG. 4, the cover glass plate 145 of FIG. 3 is eliminated because the glass containment plate 140′, i.e., the quantum dot plate, can serve as the protective cover glass.

In the quantum dot structure illustrated in FIGS. 3 and 4, the opposing, sealed glass panels comprise one cavity glass 140a, 160a and one sealing glass 140b, 160b. The sealing glass 140b, 160b is typically a relatively thin (about 100 μm) display grade glass, such as Willow which is a very thin (typically 100 μm) version of EAGLE XG® display glass available from Corning, Incorporated. A suitable cavity can be provided in the cavity glass 140a, 160a by any conventional or yet to be developed glass molding or glass machining technique including, for example, micromachining, laser-assisted machining or milling, laser ablation, etching, or combinations thereof. Sputtered glass can then be deposited on the underside of the sealing glass 140b, 160b and a laser can be used to peripherally bond the sealing glass 140b, 160b to the cavity glass while the quantum dots are resting in the cavity.

According to one set of contemplated embodiments, sealed glass panels for containing the aforementioned quantum dots may be constructed by providing a relatively low melting temperature (i.e., low T_{g}) glass sealing strip along a peripheral portion of a sealing surface of the sealing glass, the cavity glass, or both. In this manner, the cavity glass and the sealing glass, when brought into a mating configuration, cooperate with the glass sealing strip to define an interior volume that contains the quantum dots. The glass sealing strip may be deposited via physical vapor deposition, for example, by sputtering from a sputtering target.

A focused laser beam can be used to locally melt the low melting temperature glass sealing strip adjacent glass substrate material to form a sealed interface. In one approach, the laser can be focused through either the cavity glass or the sealing glass and then positionally scanned to locally heat the glass sealing strip and adjacent portions of the cavity glass and sealing glass. In order to affect local melting of the glass sealing strip, the glass sealing strip is preferably at least about 15% absorbing at the laser processing wavelength. The cavity glass and the sealing glass are typically transparent (e.g., at least 50%, 70%, 80% or 90% transparent) at the laser processing wavelength.

In an alternate embodiment, in lieu of forming a patterned glass sealing strip, a blanket layer of sealing (low melting temperature) glass can be formed over substantially all of a surface of sealing glass. An assembled structure comprising the cavity glass/sealing glass layer/sealing glass can be assembled as above, and a laser can be used to locally-define the sealing interface between the two substrates.

Laser 500 can have any suitable output to affect sealing. An example laser is a UV laser such as a 355 nm laser, which lies in the range of transparency for common display glasses. A suitable laser power can range from about 5 W to about 6.15 W.A translation rate of the laser (i.e., sealing rate) can range from about 1 mm/sec to 100 mm/sec, such as 1, 2, 5, 10, 20, 50 or 100 mm/sec. The laser spot size (diameter) can be about 0.5 to 1 mm.

The width of the sealed region, which can be proportional to the laser spot size, can be about 0.1 to 2 mm, e.g., 0.1, 0.2, 0.5, 1, 1.5 or 2 mm. A total thickness of a glass sealing layer can range from about 100 nm to 10 microns. In various embodiments, a thickness of the layer can be less than 10 microns, e.g., less than 10, 5, 2, 1, 0.5, or 0.2 microns. Example glass sealing layer thicknesses include 0.1, 0.2, 0.5, 1, 2, 5 or 10 microns.

In various embodiments of the present disclosure, the material of the glass sealing strip is transparent and/or translucent, relatively thin, impermeable, “green,” and configured to form hermetic seals at low temperatures and with sufficient seal strength to accommodate large differences in CTE between the sealing material and the adjacent glass substrates. Further, it may be preferable to ensure that the material of the sealing strip is free of fillers, binders, and/or organic additives. The low melting temperature glass materials used to form the sealing material may or may not be formed from glass powders or ground glass.

In general, suitable sealing materials include low T_{g} glasses and suitably reactive oxides of copper or tin. The glass sealing material can be formed from low T_{g} materials such as phosphate glasses, borate glasses, tellurite glasses and chalcogenide glasses. As defined herein, a low T_{g} glass material has a glass transition temperature of less than 400° C., e.g., less than 350° C., 300° C., 250° C., or 200° C. Example borate and phosphate glasses include tin phosphates, tin fluorophosphates, and tin fluoroborates. Sputtering targets can include such glass materials or, alternatively, precursors thereof. Example copper and tin oxides are CuO and SnO, which can be formed from sputtering targets comprising pressed powders of these materials.

Optionally, glass sealing compositions can include one or more dopants, including but not limited to tungsten, cerium and niobium. Such dopants, if included, can affect, for example, the optical properties of the glass layer, and can be used to control the absorption by the glass layer of laser radiation. For instance, doping with ceria can increase the absorption by a low T_{g} glass barrier at laser processing wavelengths.

Example tin fluorophosphate glass compositions can be expressed in terms of the respective compositions of SnO, SnF₂ and P₂O₅ in a corresponding ternary phase diagram. Suitable tin fluorophosphates glasses include 20-100 mol % SnO, 0-50 mol % SnF₂ and 0-30 mol % P₂O₅. These tin fluorophosphates glass compositions can optionally include 0-10 mol % WO₃, 0-10 mol % CeO₂ and/or 0-5 mol % Nb₂O₅.

For example, a composition of a doped tin fluorophosphate starting material suitable for forming a glass sealing layer comprises 35 to 50 mole percent SnO, 30 to 40 mole percent SnF₂, 15 to 25 mole percent P₂O₅, and 1.5 to 3 mole percent of a dopant oxide such as WO₃, CeO₂ and/or Nb₂O₅.

A tin fluorophosphate glass composition according to one particular embodiment is a niobium-doped tin oxide/tin fluorophosphate/phosphorus pentoxide glass comprising about 38.7 mol % SnO, 39.6 mol % SnF₂, 19.9 mol % P₂O₅ and 1.8 mol % Nb₂O₅. Sputtering targets that can be used to form such a glass layer may include, expressed in terms of atomic mole percent, 23.04% Sn, 15.36% F, 12.16% P, 48.38% 0 and 1.06% Nb.

A tin phosphate glass composition according to an alternate embodiment comprises about 27% Sn, 13% P and 60% O, which can be derived from a sputtering target comprising, in atomic mole percent, about 27% Sn, 13% P and 60% O. As will be appreciated, the various glass compositions disclosed herein may refer to the composition of the deposited layer or to the composition of the source sputtering target.

As with the tin fluorophosphates glass compositions, example tin fluoroborate glass compositions can be expressed in terms of the respective ternary phase diagram compositions of SnO, SnF₂ and B₂O₃. Suitable tin fluoroborate glass compositions include 20-100 mol % SnO, 0-50 mol % SnF₂ and 0-30 mol % B₂O₃. These tin fluoroborate glass compositions can optionally include 0-10 mol % WO₃, 0-10 mol % CeO₂ and/or 0-5 mol % Nb₂O₅.

Additional aspects of suitable low T_{g} glass compositions and methods used to form glass sealing layers from these materials are disclosed in commonly-assigned U.S. Pat. No. 5,089,446 and U.S. patent application Ser. Nos. 11/207,691, 11/544,262, 11/820,855, 12/072,784, 12/362,063, 12/763,541 and 12/879,578.

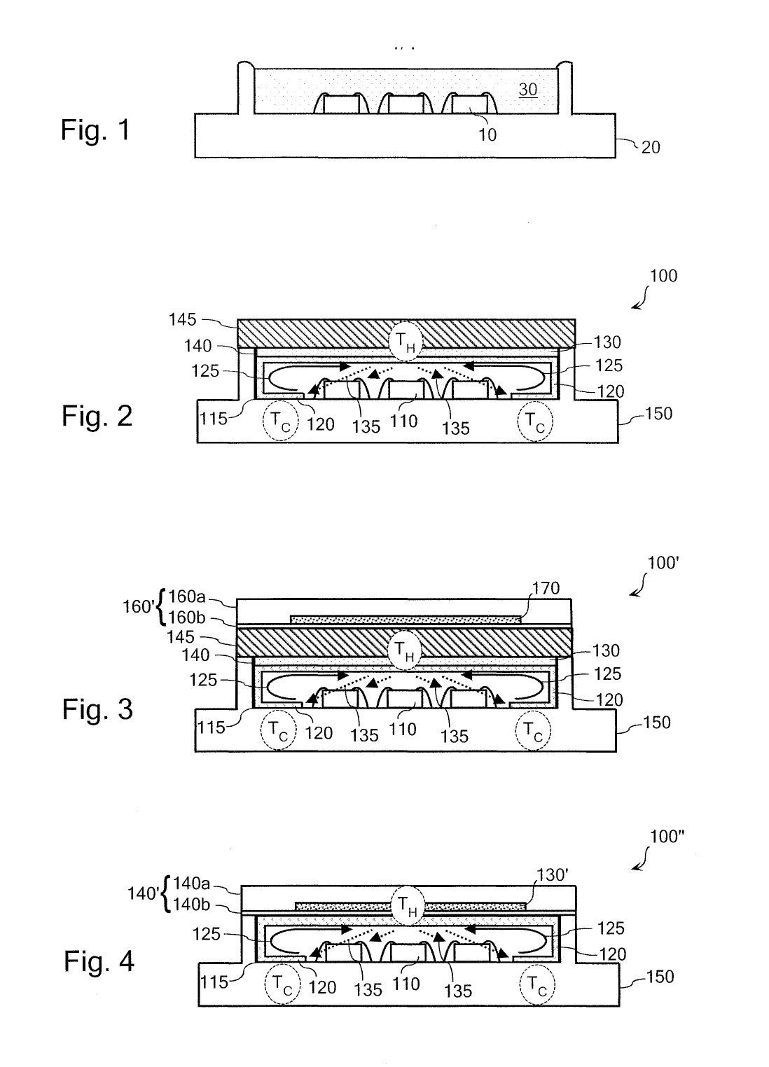

For LED lighting device configurations like that illustrated in FIG. 1, the heat flow in the COB array is vertical from the phosphor through the thin (˜5 μm thick) GaN LED and the underlying sapphire substrate to the heat sink. Heat flow H (watts) is proportional to the associated temperature gradient, which in one dimension x is dt/dx. Mathematically

$$H = k A \frac{d T}{d x} \qquad ( 1 )$$

where k is the thermal conductivity of the material and A is the cross-sectional area of an infinitesimal slab of thickness dx through which the heat flows. If the heat flow is confined to one dimension in an insulated thermal path, then the solution to equation 1 is simply

$$Δ T ≡ {T}_{2} - {T}_{1} = \frac{HL}{kA} = {R}_{th} H \qquad ( 2 )$$

where Rₜₕ is defined as the thermal resistance and L is the length of the thermal path.

The array of FIG. 1 can be modeled as a one-dimensional heat flow and the thermal resistance can be calculated using equation (2) above. Working under the assumption that a 1000 lumen array will require about 10 watts electrical input, of which about 5 watts is dissipated as heat in the LED, the remaining 5 watts is emitted as blue light. In the color conversion process, about 1.3 watts is lost as heat in the phosphor, leaving about 3.7 watts total light output. The hottest plane in the package is the surface of the phosphor. The array can be modeled as two thermal resistances in series, i.e., the phosphor-in-silicone as the first thermal resistance and the sapphire LED substrate as the second thermal resistance. The GaN film is so thin, that its thermal resistance is negligible.

Relevant specifications for the thermal model are shown in the following table:

| | |
|---|---|
| Forward Voltage | 12.2 volts |
| Operating Current | 1050 mA |
| Junction-to-Case Thermal Resistance | 0.7 deg/Watt |
| LED lateral dimensions | 1.5 mm × 1.5 mm |
| LED thickness | 0.125 mm |
| Phosphor layer thickness (above | 0.757 mm |
| LED) | |
| Total die area | 9 × (1.5 mm)² = 36 mm² |

Since the thermal conductivity of sapphire is 17.35 watts/m-K at 70 degrees C., the thermal resistance (equation (2)) of the 36 mm² area, 0.125 mm thick sapphire is Rₛ=0.2 degrees/watt. The temperature rise in the phosphor layer is more complicated since the heat load is distributed throughout the film. Blue light would be expected to decay exponentially according to Beer's Law due to absorption and scatter, so the associated heat load should have the same distribution. Assuming 90% is absorbed in the t=0.757 mm thick phosphor layer, the absorption depth d, is about 0.3285 mm. The temperature of the hottest plane can be estimated assuming that the entire 1.3 watts generated in the phosphor flows through an equivalent thickness given by

$${t}_{eq} = d - \frac{t {e}^{- t / d}}{1 - {e}^{- t / d}} \qquad ( 3 )$$

with t=0.757 mm and d=0.3285 mm, the equivalent thickness t_{eq}=0.244 mm. Assuming that the thermal conductivity of the phosphor-in-silicone is 0.22 watts/m-K, the same as silicone, then the thermal resistance of the phosphor layer is Rₚ=30.8 degrees/watt, about 60 times larger than the thermal resistance of the sapphire.

Using these data, we can estimate the temperature rise of the GaN LED and the phosphor film. Given an electrical input power of 12.8 W (12.2 volts×1.05 amps), we have 8.1 watts flowing through the sapphire and 1.66 watts dissipated in the phosphor. Assuming the heat sink temperature is 85° C., the temperatures of the LED and phosphor planes would be 87° C. and 138° C., respectively. Turning to the LED lighting devices 100, 100′, 100″ of FIGS. 2-4, it is contemplated that temperatures in the vicinity of the distributed color conversion medium 130, 130′ would be well below 138° C. under similar conditions, allowing the LED(s) of the device to be driven harder, increasing total light output.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Rather, the claims appended hereto should be taken as the sole representation of the breadth of the present disclosure and the corresponding scope of the various inventions described herein. Further, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects.

It is noted that recitations herein of a component of the present disclosure being “configured” in a particular way, to embody a particular property, or to function in a particular manner, are structural recitations, as opposed to recitations of intended use. More specifically, the references herein to the manner in which a component is “configured” denotes an existing physical condition of the component and, as such, is to be taken as a definite recitation of the structural characteristics of the component. It is also noted that recitations herein of “at least one” component, element, etc., should not be used to create an inference that the alternative use of the articles “a” or “an” should be limited to a single component, element, etc.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention it is noted that the terms “about” and “approximately” are utilized herein to represent the inherent degree of uncertainty that may be attributed to any quantitative comparison, value, measurement, or other representation. The terms are also utilized herein to represent the degree by which a quantitative representation may vary from a stated reference without resulting in a change in the basic function of the subject matter at issue.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

What is claimed is:

1. A lighting device comprising a chip-on-board (COB) light emitting diode (LED) light source, a phase transfer fluid disposed in a hermetically sealed phase transfer fluid chamber, a phase transfer fluid wicking structure, a distributed color conversion medium, and a glass containment plate, wherein:
the color conversion medium is distributed in two dimensions over an emission field of the lighting device within the glass containment plate.
the COB LED light source comprises a thermal heat sink framework and at least one LED and defines the hermetically sealed phase transfer fluid chamber in which the phase transfer fluid is disposed;
the glass containment plate is positioned over the hermetically sealed phase transfer fluid chamber, contains the distributed color conversion medium, and defines high operating temperature regions T_{H} of the lighting device;
the thermal heat sink framework of the light source defines low operating temperature regions T_{C} of the lighting device; and
the phase transfer fluid wicking structure is transparent to at least a portion of the operating wavelength bandwidth of the LED and is configured within the hermetically sealed phase transfer fluid chamber to
(i) encourage the transport of phase transfer fluid along a fluid transport path extending from low operating temperature regions T_{C} of the lighting device to high operating temperature regions T_{H} of the lighting device within the fluid chamber,
(ii) permit vaporization of the transported phase transfer fluid in the high operating temperature regions T_{H} of the lighting device, and
(iii) receive condensed phase transfer fluid vapor in the low operating temperature regions T_{C} of the lighting device for return transport to the high operating temperature regions T_{H} of the lighting device via the phase transfer fluid wicking structure.

2. The lighting device as claimed in claim 1 wherein the phase transfer fluid wicking structure encourages the transport of phase transfer fluid through capillary action.

3. The lighting device as claimed in claim 1 wherein the phase transfer fluid wicking structure comprises a wicking media disposed on an interior surface of the hermetically sealed phase transfer fluid chamber.

4. The lighting device as claimed in claim 1 wherein the phase transfer fluid wicking structure comprises glass frit disposed on an interior surface of the hermetically sealed phase transfer fluid chamber.

5. The lighting device as claimed in claim 1 wherein the phase transfer fluid wicking structure comprises fluid transfer grooves, a glass mesh, a glass fiber network, or other topographical formations in an interior surface of the hermetically sealed phase transfer fluid chamber.

6. The lighting device as claimed in claim 1 wherein the fluid wicking structure extends from a chip-on-board portion of the thermal heat sink framework to portions of the hermetically sealed phase transfer fluid chamber in closest thermal communication with the distributed color conversion medium.

7. The lighting device as claimed in claim 1 wherein the fluid wicking structure extends from the low operating temperature regions T_{C} of the lighting device to the high operating temperature regions T_{H} of the lighting device.

8. The lighting device as claimed in claim 7 wherein the fluid transport path of the wicking structure extends along an indirect route from the low operating temperature regions T_{C} of the lighting device to the high operating temperature regions T_{H} of the lighting device.

9. The lighting device as claimed in claim 8 wherein the indirect route is configured such that a significant portion of the fluid transport path of the wicking structure lies outside of a vapor transport path defined between the high operating temperature regions T_{H} of the lighting device and the low operating temperature regions T_{C} of the lighting device.

10. The lighting device as claimed in claim 1 wherein:
the glass containment plate comprises a glass matrix; and
the distributed color conversion medium comprises a phosphor distributed in the glass matrix.

11. The lighting device as claimed in claim 1 wherein:
the glass containment plate comprises a glass frame; and
the distributed color conversion medium comprises a quantum dot structure contained within an interior volume of the glass frame.

12. The lighting device as claimed in claim 1 wherein:
the glass containment plate comprises a glass matrix;
the distributed color conversion medium comprises a phosphor distributed in the glass matrix;
the lighting device further comprises a quantum dot plate disposed over the glass containment plate to define a supplemental emission field of the lighting device; and
the emission field defined by the distributed phosphor color conversion medium is spatially congruent with, but spectrally distinct from, the supplemental emission field defined by the quantum dot plate.

13. The lighting device as claimed in claim 12 wherein:
the quantum dot plate that is disposed over the glass containment plate comprises a quantum dot structure and opposing glass panels that are sealed at complementary edges to define an interior volume; and
the quantum dot structure is contained within the interior volume of the quantum dot plate.

14. The lighting device as claimed in claim 12 wherein an emission spectrum of the emission field defined by the quantum dot plate adds optical warmth to an emission spectrum of the emission field defined by the distributed phosphor color conversion medium.

15. The lighting device as claimed in claim 1 wherein:
the COB LED light source comprises an LED array; and
the light source encapsulant is distributed over the LED array.

16. A lighting device comprising a chip-on-board (COB) light emitting diode (LED) light source, a phase transfer fluid disposed in a hermetically sealed phase transfer fluid chamber, a phase transfer fluid wicking structure, a distributed color conversion medium, and a glass containment plate, wherein:
the color conversion medium is distributed in two dimensions over an emission field of the lighting device within the glass containment plate.
the COB LED light source comprises a thermal heat sink framework and at least one LED and defines the hermetically sealed phase transfer fluid chamber in which the phase transfer fluid is disposed;
the glass containment plate is positioned over the hermetically sealed phase transfer fluid chamber and contains the distributed color conversion medium; and
the phase transfer fluid wicking structure is transparent to at least a portion of the operating wavelength bandwidth of the LED and is configured within the hermetically sealed phase transfer fluid chamber to encourage transport of phase transfer fluid, permit vaporization of transported phase transfer fluid, and receive condensed phase transfer fluid vapor.
